(19) United States
(12) Patent Application Publication
(10) Pub. No.: US 2025/0189903 A1
(43) Pub. Date: Jun. 12, 2025

(54) INSPECTION METHOD, RESIN SOLUTION, RESIST COMPOSITION OR THERMOSETTING COMPOSITION, METHOD OF PRODUCING RESIN COMPOSITION, AND METHOD OF PRODUCING RESIST COMPOSITION OR THERMOSETTING COMPOSITION

(71) Applicant: TOKYO OHKA KOGYO CO., LTD., Kawasaki-shi (JP)

(72) Inventors: Komei HIRAHARA, Kawasaki-shi (JP); Yoshihito KAI, Kawasaki-shi (JP); Akihiko NAKATA, Kawasaki-shi (JP)

(21) Appl. No.: 18/962,049

(22) Filed: Nov. 27, 2024

(30) Foreign Application Priority Data
Dec. 8, 2023 (JP) 2023-207435

(51) Int. Cl. G03F 7/00; G01N 21/95; G01N 21/956

(52) U.S. Cl. CPC G03F 7/7065; G01N 21/9501; G01N 21/956

(57) ABSTRACT

An inspection method including a step V of filtering a precursor composition V containing a polymer compound and a solvent V, a step X1 of coating a substrate X with a resin composition X containing the precursor composition to form a coating film X, a step X2 of removing the coating film X from the substrate X using a removal solvent X including at least one selected from the group consisting of an organic solvent X, an alkali developing solution X, and water; and a step X3 of measuring the number of defects on the substrate X after the coating film X is removed, using a defect inspection device.

### INCORPORATION BY REFERENCE TO ANY PRIORITY APPLICATIONS

The present application claims priority to Japanese Patent Application No. 2023-207435, filed Dec. 8, 2023, the entire content of which is incorporated herein by reference.

### BACKGROUND OF THE INVENTION

### Field of the Invention

The present invention relates to an inspection method, a resin solution, a resist composition or a thermosetting composition, a method of producing a resin composition, and a method of producing a resist composition or a thermosetting composition.

### Description of the Related Art

It is known that a semiconductor device is manufactured by forming a fine electronic circuit pattern on a substrate using a photolithography technology.

Specifically, a resist film obtained by using an actinic ray-sensitive or radiation-sensitive composition (hereinafter, also referred to as “resist composition”) is formed on a substrate, and the resist film is subjected to various treatments such as an exposure treatment of irradiating the resist film with light, a development treatment using a developing solution, and as necessary, a rinsing treatment using a rinsing liquid, to obtain a patterned resist film. An electronic circuit pattern is formed by performing various treatments using the patterned resist film obtained as described above as a mask.

In such a semiconductor device forming step, a pattern forming method that enables suppression of occurrence of defects is required in order to further improve the yield of the semiconductor device to be obtained. In recent years, the manufacture of semiconductor devices having a node size of 10 nm or less has been examined, and this tendency has been more significant.

Meanwhile, foreign matter contained in the resist composition may be one of the causes of defects in the pattern.

For example, Patent Document 1 suggests a method of automatically inspecting whether or not foreign matter is attached to a member to be coated, such as a substrate, before and after coating with a coating material or before or after the coating, and sorting the quality so that defective products are not transported to the next step.

### CITATION LIST

### Patent Document

Patent Document 1 Japanese Unexamined Patent Application, First Publication No. S60-177624

### SUMMARY OF THE INVENTION

### Technical Problem

However, in recent years, further miniaturization of electronic circuit patterns has progressed, and even slight foreign matter may cause a fine defect and may have a significant influence on the performance of a semiconductor device. Therefore, in the process of manufacturing a semiconductor device, an inspection method that enables a fine defect to be found has been required.

The present invention has been made in consideration of the above-described circumstances, and an object thereof is to provide an inspection method that enables a fine defect to be found, a resin solution in which the number of defects is reduced by the inspection method, a resist composition or a thermosetting composition in which the number of defects is reduced by the inspection method, a method of producing a resin composition, and a method of producing a resist composition or the thermosetting composition.

### Solution to Problem

In order to solve the above-described problems, the present invention has adopted the following configurations.

That is, according to a first aspect of the present invention, there is provided an inspection method including: a step V of filtering a precursor composition V containing a polymer compound and a solvent V; a step X1 of coating a substrate X with a resin composition X containing the precursor composition to form a coating film X; a step X2 of removing the coating film X from the substrate X using a removal solvent X including at least one selected from the group consisting of an organic solvent X, an alkali developing solution X, and water; and a step X3 of measuring the number of defects on the substrate X after the coating film X is removed, using a defect inspection device.

According to a second aspect of the present invention, there is provided a resin solution including: a polymer compound; and a solvent V, in which the number of defects having a size of 12.5 nm or greater per 1 cm², which is measured under the following measurement conditions, is 2 or less.

### Measurement Conditions

(1) A precursor composition containing the polymer compound and the solvent V is filtered.
(2) A substrate X is coated with a resin composition X containing the precursor composition to form a coating film X.
(3) The coating film X is removed from the substrate X using a removal solvent X including at least one selected from the group consisting of an organic solvent, an alkali developing solution, and water.
(4) The number of defects on the substrate X after the coating film X is removed is measured using a defect inspection device.

According to a third aspect of the present invention, there is provided a resist composition or a thermosetting composition, which contains the resin solution according to the second aspect.

According to a fourth aspect of the present invention, there is provided a method of producing a resin composition, including: a step V of filtering a precursor composition containing a polymer compound and a solvent V; a step X1 of coating a substrate X with a resin composition X containing the precursor composition to form a coating film X; a step X2 of removing the coating film X from the substrate X using a removal solvent X including at least one selected from the group consisting of an organic solvent, an alkali developing solution, and water; a step X3 of measuring the number of defects on the substrate X after the coating film X is removed, using a defect inspection device; and a step R1 of providing a resin composition satisfying a predetermined number of defects in the step X3.

According to a fifth aspect of the present invention, there is provided a method of producing a resist composition or a thermosetting composition, the method including: a step R11 of providing a resin composition by the method of producing a resin composition according to the fourth aspect; and a step R12 of providing a resist composition or a thermosetting composition containing the resin composition.

### Advantageous Effects of Invention

According to the present invention, it is possible to provide an inspection method that enables a fine defect to be found, a resin solution in which the number of defects is reduced by the inspection method, a resist composition or a thermosetting composition in which the number of defects is reduced by the inspection method, a method of producing a resin composition, and a method of producing a resist composition or the thermosetting composition.

### BRIEF DESCRIPTION OF THE DRAWINGS

FIG. 1 is a schematic view showing defect positions on a substrate X, which are measured in a step X41.

FIG. 2 is a schematic view showing defect positions derived from the substrate X and a resin composition X, which are measured in a step X42.

FIG. 3 is a schematic view showing defect positions derived from the resin composition X, which are obtained by subtracting the defect positions measured in the step X41 from the defect positions measured in the step X42.

### DETAILED DESCRIPTION OF THE PREFERRED EMBODIMENT

### First Aspect: Inspection Method

An inspection method according to the present embodiment includes a step V of filtering a precursor composition V containing a polymer compound and a solvent V, a step X1 of coating a substrate X with a resin composition X containing the precursor composition to form a coating film X, a step X2 of removing the coating film X from the substrate X using a removal solvent X including at least one selected from the group consisting of an organic solvent X, an alkali developing solution X, and water, and a step X3 of measuring the number of defects on the substrate X after the coating film X is removed, using a defect inspection device.

Hereinafter, each step will be described.

### Step V

A method of filtering the precursor composition V is not particularly limited, and examples thereof include filtration using a filter. The filter pore diameter and the material are not particularly limited, and can be appropriately adjusted according to the composition. The filter that has been washed with a solvent in advance may be used. In a filter filtration step, a plurality of kinds of filters may be connected and used in series or in parallel. In a case where a plurality of kinds of filters are used, at least one filter with a pore diameter and a material different from those of other filters may be used in combination. In addition, various materials may be filtered a plurality of times, and the step of filtering materials a plurality of times may be a circulation filtration step.

The precursor composition V may be filtered using, for example, a filter consisting of at least one porous film of polyimide, polyamideimide, polyimide, polyamideimide, or polyethylene. Examples of the porous polyimide film and the porous polyamide-imide film include those described in Japanese Unexamined Patent Application, First Publication No. 2016-155121.

In addition, the filter may be a filter in which eluted substances are reduced as disclosed in Japanese Unexamined Patent Application, First Publication No. 2016-201426.

The pore diameter of the filter is not particularly limited, but is preferably 50 nm or less, more preferably 20 nm or less, and still more preferably 10 nm or less.

In the present embodiment, the filter may be one stage or two or more stages, but two or more stages are preferable.

The pore diameter of the filter in the first stage is preferably 20 nm or less, more preferably 10 nm or less, and still more preferably 6 nm or less. The pore diameter of the filter in the second and subsequent stages is preferably 10 nm or less, more preferably 5nm or less, and still more preferably 2 nm or less.

In addition to the filter filtration, impurities may be removed by an adsorbing material, or the filter filtration and the adsorbing material may be used in combination. As the adsorbing material, a known adsorbing material can be used, and for example, an inorganic adsorbing material such as silica gel or zeolite, or an organic adsorbing material such as activated carbon can be used. Examples of the metal adsorbing material include those disclosed in Japanese Unexamined Patent Application, First Publication No. 2016-206500.

In addition, examples of a method of removing impurities such as metals include a method of selecting a raw material having a low metal content as a raw material, a method of performing filter filtration on a raw material, and a method of performing distillation under conditions in which contamination is suppressed as much as possible by lining the inside of a device with polytetrafluoroethylene or the like. The preferable conditions in the filter filtration performed on the raw materials are the same as the above-described conditions.

### Polymer Compound

The polymer compound is not particularly limited, and examples thereof include a polymer compound contained in a coating material to be applied to a material to be coated, such as a substrate, in a process of manufacturing a semiconductor device. Specific examples of the polymer compound include a base material component of a resist composition, a thermosetting composition for forming an antireflection film, and a material for forming a dicing protective film.

### Solvent

The solvent is not particularly limited as long as the solvent can dissolve the polymer compound. Specific examples of the solvent include polar solvents such as water, a lactone solvent, a ketone solvent, an alcohol solvent, an ester solvent, an ether solvent, an aromatic organic solvent, a hydrocarbon solvent, and dimethyl sulfoxide (DMSO).

The solid content concentration of the precursor composition is not particularly limited, but is preferably 50% by mass or less, more preferably 35% by mass or less, still more preferably 20% by mass or less, and even still more preferably 15% by mass or less.

### Step X1

Examples of a method of forming the coating film X on the substrate X using the precursor composition include a method of coating the substrate X with the precursor composition. In addition, other examples of the coating method include a coating method using a coater cup and a coating method using an organic development unit. In addition, a coating method performed using a spin coating method with a spinner is also preferable. The rotation speed in a case of performing spin coating using a spinner is preferably in a range of 500 to 3000 rpm.

In a case where a coater is used, the jetting time is not particularly limited and may be appropriately changed according to the solid content concentration of the composition.

It is preferable that the substrate X is coated with the precursor composition and dried.

Examples of a drying method include a method of heating and drying the substrate. The heating can be carried out by means provided in a typical exposure machine and/or a typical development machine or may be carried out using a hot plate or the like. The heating temperature is preferably in a range of 80° C. to 150°° C., more preferably in a range of 80°° C. to 140° C., and still more preferably in a range of 80° C. to 130° C. The heating time is preferably in a range of 30 to 1,000 seconds, more preferably in a range of 60 to 800 seconds, and still more preferably in a range of 60 to 600 seconds. In one aspect, it is preferable that the heating is carried out at 100° C. for 60 seconds.

The film thickness of the coating film X is not particularly limited, but is preferably in a range of 10 to 1000 nm and more preferably in a range of 10 to 120 nm. Among these, it is preferable to consider the film thickness for each use application of the precursor composition, and for example, in a case where the precursor composition is a base material component for a resist composition and is provided for pattern formation by EUV exposure or EB exposure, the film thickness of the coating film X is more preferably in a range of 10 to 100 nm and still more preferably in a range of 15 to 70 nm. In addition, for example, in a case where the precursor composition is a base material component for a resist composition and is provided for pattern formation by ArF exposure, the film thickness of the coating film X is more preferably in a range of 10 to 120 nm and still more preferably in a range of 15 to 90 nm.

Resin composition X

The resin composition X is not particularly limited as long as the composition contains the precursor composition. For example, the precursor composition itself may be used as the resin composition X, or the precursor composition may be mixed with an optional component to obtain the resin composition X.

In the present embodiment, from the viewpoint of inspecting defects derived from the precursor composition with higher accuracy, it is preferable that the resin composition is non-photosensitive.

In addition, in the present embodiment, from the viewpoint of inspecting the defects derived from the precursor composition with higher accuracy, it is preferable that the resin composition X is formed of the polymer compound and the solvent V.

### Substrate X

Examples of the substrate X include a substrate used for producing an integrated circuit element, and a silicon wafer is preferable. The substrate X may be a reproduced wafer.

From the viewpoint of further improving the inspection accuracy, the number of defects (number of defects on original substrate) present on the substrate X used in the step X1 before the application of the substrate X to the step X1 is preferably 2.00 defects/cm² or less, more preferably 1.20 defects/cm² or less, still more preferably 0.75 defects/cm² or less, and particularly preferably 0.15 defects/cm² or less. Further, the lower limit thereof is, for example, 0.00 defects/cm² or greater.

Among these, from the viewpoint of further improving the inspection accuracy, the number of defects having a size of 12.5 nm or greater, which are present on the substrate X before the substrate X used in the step X1 is applied to the step X1, is preferably 2.00 defects/cm² or less, more preferably 1.20 defects/cm² or less, still more preferably 0.75 defects/cm² or less, and particularly preferably 0.15 defects/cm² or less. Further, the lower limit thereof is, for example, 0.00 defects/cm² or greater. The upper limit of the size of the defect is not particularly limited, but is, for example, 5 μm or less, and the same applies to the defects described in each step below. In a case where the number of defects on the substrate X to be used in the step X1 is large, scattering may occur during the defect inspection on the substrate performed in the step X3, which may hinder accurate measurement of the number of defects. Therefore, from the viewpoint that the accuracy of the defect inspection on the substrate in the step X3 is more excellent (and from the viewpoint that the inspection accuracy of the present inspection method is further improved), it is preferable to use a substrate having high cleanliness (substrate having a small number of defects on the original substrate) as the substrate X to be used in the step X1.

The defect inspection on the substrate X can be measured by a defect inspection device (for example, a dark-field defect inspection device: Surfscan (registered trademark) SP7^{XP} or the like, manufactured by KLA-Tencor).

### Step X2

The removal solvent X used in the step X2 includes at least one selected from the group consisting of an organic solvent X, an alkali developing solution X, and water (hereinafter, also referred to as “X component”).

The X component may be used alone or in the form of a mixture of a plurality of kinds thereof.

The content of the X component (the total amount in a case where a plurality of solvents are mixed) in the removal solvent is preferably in a range of 60% to 100% by mass, more preferably in a range of 85% to 100% by mass, still more preferably in a range of 90% to 100% by mass, particularly preferably in a range of 95% to 100% by mass, and most preferably in a range of 98% to 100% by mass with respect to the total amount of the removal solvent X.

Among these, it is preferable that the organic solvent X substantially does not contain water from the viewpoint of improving the inspection accuracy. The expression “the organic solvent X substantially does not contain water” denotes that the moisture content in the organic solvent X is 10% by mass or less, preferably 5% by mass or less, more preferably 1% by mass or less, and still more preferably 0% by mass.

### Organic Solvent X

The organic solvent X is not particularly limited as long as the coating film X formed in the step X1 can be removed from the substrate X, but among these, an organic solvent (for example, in a case where the precursor composition is a base material component of a resist composition, the organic solvent corresponds to an organic solvent in which a resist component is diluted) contained in the precursor composition is preferable, the organic solvent preferably includes one or more selected from the group consisting of an ester-based organic solvent, an alcohol-based organic solvent, and a ketone-based organic solvent and is more preferably formed of these groups.

Examples of the ester-based organic solvent include propylene glycol monoalkyl ether carboxylate, lactic acid ester, acetic acid ester, lactone, and alkoxypropionic acid ester.

As the propylene glycol monoalkyl ether carboxylate, for example, propylene glycol monomethyl ether acetate (PGMEA), propylene glycol monomethyl ether propionate, or propylene glycol monoethyl ether acetate is preferable, and propylene glycol monomethyl ether acetate (PGMEA) is more preferable.

As the lactic acid ester, ethyl lactate, butyl lactate, or propyl lactate is preferable. As the acetic acid ester, methyl acetate, ethyl acetate, butyl acetate, isobutyl acetate, propyl acetate, isoamyl acetate, methyl formate, ethyl formate, butyl formate, propyl formate, or 3-methoxybutyl acetate is preferable.

As the alkoxypropionic acid ester, methyl 3-methoxypropionate (MMP) or ethyl 3-ethoxypropionate (EEP) is preferable.

As the lactone, γ-butyrolactone is preferable.

Examples of the alcohol-based organic solvent include propylene glycol monoalkyl ether.

As the propylene glycol monoalkyl ether, propylene glycol monomethyl ether (PGME) or propylene glycol monoethyl ether (PGEE) is preferable.

Examples of the ketone-based organic solvent include a chain-like ketone and a cyclic ketone.

As the chain-like ketone, 1-octanone, 2-octanone, 1-nonanone, 2-nonanone, acetone, 2-heptanone, 4-heptanone, 1-hexanone, 2-hexanone, diisobutyl ketone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, or methyl amyl ketone is preferable.

As the cyclic ketone, methylcyclohexanone, isophorone, or cyclohexanone is preferable.

The organic solvent X may be used alone or in the form of a mixture of two or more kinds thereof.

Among these, the organic solvent X preferably includes one or more selected from the group consisting of propylene glycol monomethyl ether acetate (PGMEA), propylene glycol monomethyl ether (PGME), methyl amyl ketone, cyclohexanone, ethyl lactate, butyl acetate, and γ-butyl lactone and is more preferably formed of these groups.

### Alkali Developing Solution X

Examples of the alkali developing solution X include a 0.1% to 10 mass % tetramethylammonium hydroxide (TMAH) aqueous solution.

In the present embodiment, the step X2 may be applied in a state where the coating film X has not been subjected to an exposure treatment by irradiation with an actinic ray or radiation or may be applied in a state where the coating film X has been subjected to an exposure treatment by irradiation with an actinic ray or radiation.

From the viewpoint of inspecting defects derived from the precursor composition with higher accuracy, it is preferable that the step X2 is applied in a state where the coating film X has not been subjected to an exposure treatment by irradiation with actinic rays or radiation.

### Step X3

The step X3 is a step of measuring the number of defects on the substrate X after the coating film X is removed by the step X2, using a defect inspection device. Specifically, the number of defects (preferably the number of defects having a size of 12.5 nm or more) present on the substrate X is measured.

The defect inspection of the substrate X in the step X3 can be measured by a defect inspection device (for example, a dark field defect inspection device: Surfscan (registered trademark) SP7^{XP} or the like, manufactured by KLA-Tencor).

The number of defects (preferably the number of defects having a size of 12.5 nm or greater) present on the substrate X after the removal with the removal solvent is measured by carrying out the step X3.

### Optional Steps

The inspection method according to the present embodiment may include steps other than the step V, the step X1, the step X2, and the step X3.

Hereinafter, each optional step will be described.

### Step X2A

The removal solvent X may be used after filtration (step X2A). A method of filtering the removal solvent X is the same as the method of filtering the precursor composition V in the step V.

### Step Z

In the inspection method according to the present embodiment, a step Z including a step Z1 of coating a substrate Z with a resist composition or a thermosetting composition containing the precursor composition V to form a coating film Z, a step Z2 of removing the coating film Z from the substrate Z using a removal solvent Z including at least one selected from the group consisting of an organic solvent Z, an alkali developing solution Z, and water, and a step Z3 of measuring the number of defects on the substrate Z after the coating film Z is removed, using the defect inspection device, may be performed.

By performing the step Z, not only defects derived from the precursor composition V but also defects derived from other components of the resist composition or the thermosetting composition can be inspected, and thus it is easy to determine the results for defects derived from the resist composition or the thermosetting composition actually used in the manufacture of a semiconductor device.

### Step Z1

A method of coating the substrate Z with the resist composition or the thermosetting composition to form the coating film Z is the same as the method of forming the coating film X on the substrate X using the precursor composition in the step X1.

### Resist Composition or Thermosetting Composition

The resist composition or thermosetting composition used in the step Z1 is not particularly limited as long as the composition contains the precursor composition V.

For example, the resist composition may contain the precursor composition V as a base material component and may contain other optional components. Typically, the resist composition contains the precursor composition V as a base material component, a photoacid generator, an acid diffusion control agent, a solvent, and other additives (a crosslinking agent, a fluorine additive, an organic acid, an additional resin for improving the performance of a resist film, a dissolution inhibitor, a plasticizer, a stabilizer, a colorant, a halation inhibitor, a dye, and the like).

Alternatively, the resist composition may contain the precursor composition V as a hydrophobic resin, a base material component, a photoacid generator, an acid diffusion control agent, a solvent, and other additives (a crosslinking agent, a fluorine additive, an organic acid, an additional resin for improving the performance of a resist film, a dissolution inhibitor, a plasticizer, a stabilizer, a colorant, a halation inhibitor, a dye, and the like).

The thermosetting composition may contain the precursor composition V, a solvent, a crosslinking agent, and a surfactant.

The solid content concentration of the resist composition or the thermosetting composition is not particularly limited, but is preferably 50% by mass or less, more preferably 35% by mass or less, still more preferably 10% by mass or less, and even still more preferably 3% by mass or less.

### Substrate Z

As the substrate Z, any one kind of the substrate X described in the step X1 can be used. From the viewpoint of measuring defects derived from the resist composition or the thermosetting composition with high accuracy, it is preferable that the substrate Z is of the same kind as the substrate X and that the substrate X itself used in the step X1 is not used as the substrate Z.

### Step Z2

The removal solvent Z used in the step Z2 can be used from the examples of the removal solvent X described in the step X2, and it is preferable that the removal solvent Z is the same as the removal solvent X used in the step X2.

### Step Z2A

The removal solvent Z may be used after filtration (step Z2A). The method of filtering the removal solvent Z is the same as the method of filtering the precursor composition V in the step V.

### Step Z3

The step Z3 can be performed in the same manner as the step X3.

### Step Y1

The inspection method according to the present embodiment may further include, before the step X1 or the step Z1, a step Y1 of detecting a position of a defect on the substrate X or the substrate Z using the defect inspection device with respect to the substrate X or the substrate Z used in the step X1 or the step Z1.

By performing the step Y1, defects derived from the substrate X or the substrate Z can be understood in advance, and thus it is easier to determine the results of the defects derived from the precursor composition V, the resist composition, or the thermosetting composition in the step X3 or the step Z3.

The defect inspection on the substrate X or the substrate Z can be measured by a defect inspection device (for example, a dark field defect inspection device: Surfscan (registered trademark) SP7^{XP} or the like, manufactured by KLA-Tencor).

### Step Y2

In the inspection method according to the present embodiment, a step Y2 including a step Y2A of coating a substrate Y with the removal solvent used in the step X2 or the step Z2 and a step Y2B of detecting the position of the defect on the substrate X or the substrate Z after the application of the removal solvent using a defect inspection device may be performed.

Since the defects derived from the removal solvent can be understood by performing the step Y, it is easier to determine the results of the defects derived from the precursor composition V in the step X3.

The step Y2A can be performed in the same manner as the step X1 or the step Z1.

The step Y2B can be performed in the same manner as the step X3 or the step Z3.

In the inspection method according to the present embodiment, both the step Y1 and the step Y2 may be performed. In a case where both the step Y1 and the step Y2 are performed, the number of defects derived from the substrate X or the substrate Z measured in the step Y1 and the number of defects derived from the removal solvent measured in the step Y2 may be subtracted from the number of defects measured in the step X3 or the step Z3. Due to the subtraction, it is easier to determine the results for the defects derived from the precursor composition V.

Further, in a case where the number of defects derived from the removal solvent (the number of defects of the removal solvent) is already known from the description in a catalog or the like, the nominal value thereof may be used as “the number of defects derived from the removal solvent measured in the step Y2” without carrying out the step Y2.

### Step X4

The inspection method according to the present embodiment may include a step X4 of superimposing position coordinates of a detection result of a defect by the step Y1 and a detection result of a defect by the step X3, and measuring the number of defects derived from the resin composition X by subtracting the number of defects detected at the same position as the position of the defect on the substrate Z detected in the step Y1 from the number of defects by the step X3.

By performing the step X4, the results of the defects derived from the resin composition X are more easily determined.

An example of the procedure of the step X4 will be described with reference to the drawings.

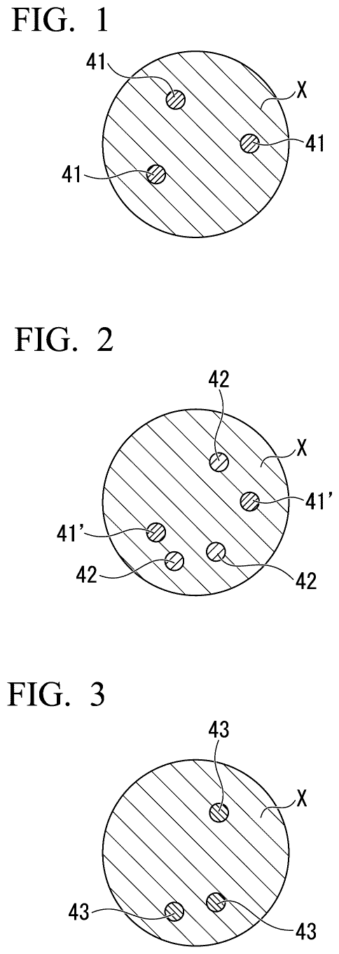

First, as shown in FIG. 1, the defect position in the substrate X is measured (step X41). In FIG. 1, the defect 41 is a defect derived from the substrate X.

Next, as shown in FIG. 2, in the substrate X after the application of the removal solvent X, the defect position in the substrate X is measured (step X42). In FIG. 2, a defect 41′ is a defect derived from the substrate X, and the defect 42 is a defect derived from the resin composition X.

Further, as shown in FIG. 3, the defect 41′ at the same position as the defect measured in the step X41 is subtracted from the defects 41′ and 42 measured in the step X42, and the number of defects 43 derived from the removal solvent X is measured (step X43).

Since the defects detected at the same position in the step X41 and the step X42 are derived from the substrate X, the defects derived from the resin composition can be appropriately measured in the step X43 by subtracting the number of defects detected at the same position.

Further, in the step X42, all the defect positions in the substrate X measured in the step X41 may not be detected. Therefore, in a case where, in the step X43, the total number of defects in the step X41 is subtracted instead of the number of defects detected at the same position in the step X41 and the step X42 from the number of defects measured in the step X42, the defects that are detected in the step X41 but are not detected in the step X42 are excessively subtracted, and thus the accurate number of defects cannot be measured.

### Step Y3

The inspection method according to the present embodiment may include a step Y3 of superimposing position coordinates of a detection result of a defect by the step Y1 and a detection result of a defect by the step Y2, and measuring the number of defects derived from the removal solvent Y by subtracting the number of defects detected at the same position as the position of the defect on the substrate Z detected in the step Y1 from the number of defects by the step Y2.

By performing the step Y3, the results of the defects derived from the resin composition X are more easily determined.

The step Y3 can be performed in the same manner as the step X4.

### Step ZA

The inspection method according to the present embodiment may include a step 74 of superimposing position coordinates of a detection result of a defect by the step Y1 and a detection result of a defect by the step Z3, and measuring the number of defects derived from the resist composition or the thermosetting composition by subtracting the number of defects detected at the same position as the position of the defect on the substrate Z detected in the step Y1 from the number of defects by the step Z3.

By performing the step Z4, the results of the defects derived from the resist composition or the thermosetting composition are more easily determined.

The step Z4 can be performed in the same manner as the step X4.

In the inspection method according to the present embodiment, the minimum value of the measurable defects is preferably 20 nm or less, more preferably 19 nm or less, still more preferably 17 nm or less, and most preferably 12.5 nm or less.

That is, in the inspection method according to the present embodiment, it is most preferable that the size of the defect measured in at least one selected from the group consisting of the step X3, the step Z3, and the step Y1 is 12.5 nm or greater.

According to the inspection method of the present embodiment, it is possible to determine a defective resin by evaluating defects of a resin raw material before preparation of a resist composition or a thermosetting composition. Therefore, improvement of the productivity of the semiconductor device can be expected by applying the inspection method according to the present embodiment.

In addition, the cause of the defects of the resist composition or the thermosetting composition is more accurately found by inspecting the number of defects of the resin composition X in advance.

### Second Aspect: Resin Solution

The resin solution according to the present embodiment contains a polymer compound and a solvent V, and the number of defects having a size of 12.5 nm or greater per 1 cm² is 2 or less, which is measured under the following measurement conditions.

### Measurement Conditions

(1) A precursor composition containing the polymer compound and the solvent V is filtered.
(2) A substrate X is coated with a resin composition X containing the precursor composition to form a coating film X.
(3) The coating film X is removed from the substrate X using a removal solvent X including at least one selected from the group consisting of an organic solvent, an alkali developing solution, and water.
(4) The number of defects on the substrate X after the coating film X is removed is measured using a defect inspection device.

In the present embodiment, the measurement can be performed under the measurement conditions (1) to (4) in the same manner as in the step V, the step X1, the step X2, and the step X3 in the inspection method according to the first aspect.

Since the resin solution according to the present embodiment has reduced defects, the resin solution is useful as a resin raw material of various materials used for manufacturing a semiconductor device.

### Third Aspect: Resist Composition Or Thermosetting Composition

The resist composition or thermosetting composition according to the present embodiment contains the resin solution according to the second aspect.

The resist composition according to the present embodiment contains, for example, the resin solution according to the second aspect as a base material component, and may contain other optional components. Typically, the resist composition contains the resin solution according to the second aspect as a base material component, a photoacid generator, an acid diffusion control agent, a solvent, and other additives (a crosslinking agent, a fluorine additive, an organic acid, an additional resin for improving the performance of a resist film, a dissolution inhibitor, a plasticizer, a stabilizer, a colorant, a halation inhibitor, a dye, and the like).

Alternatively, the resist composition may contain the resin solution according to the second aspect as a hydrophobic resin, a base material component, a photoacid generator, an acid diffusion control agent, a solvent, and other additives (a crosslinking agent, a fluorine additive, an organic acid, an additional resin for improving the performance of the resist film, a dissolution inhibitor, a plasticizer, a stabilizer, a colorant, a halation inhibitor, a dye, and the like).

The thermosetting composition according to the present embodiment may contain the precursor composition V, a solvent, a crosslinking agent, and a surfactant.

Since the resist composition or thermosetting composition according to the present embodiment contains a resin solution with reduced defects, the resist composition or thermosetting composition is suitable for manufacturing a semiconductor device.

### Fourth Aspect: Method Of Producing Resin Composition

The method of producing a resin composition according to the present embodiment includes a step V of filtering a precursor composition containing a polymer compound and a solvent V, a step X1 of coating a substrate X with a resin composition X containing the precursor composition to form a coating film X, a step X2 of removing the coating film X from the substrate X using a removal solvent X including at least one selected from the group consisting of an organic solvent, an alkali developing solution, and water, a step X3 of measuring the number of defects on the substrate X after the coating film X is removed, using a defect inspection device, and a step R1 of providing a resin composition satisfying a predetermined number of defects in the step X3.

In the present embodiment, the step V, the step X1, the step X2, and the step X3 are the same as the step V, the step X1, the step X2, and the step X3 in the inspection method according to the first aspect.

In the step R1, the resin composition satisfying the predetermined number of defects is preferably a resin composition in which the number of defects with a size of 12.5 nm or greater per 1 cm², which is measured in the step X3, is 2 or less.

According to the method of producing a resin composition of the present embodiment, a resin composition with reduced defects is obtained, and thus the resin composition can be applied to a resin raw material of various materials used for manufacturing a semiconductor device.

### Method of Producing Resist Composition or Thermosetting Composition

The method of producing a resist composition or a thermosetting composition according to the present embodiment includes a step R11 of providing a resin composition by the method of producing a resin composition and a step R12 of providing a resist composition or a thermosetting composition containing the resin composition.

According to the method of producing a resist composition or a thermosetting composition of the present embodiment, defects can be reduced, and thus a resist composition or a thermosetting composition suitable for manufacturing a semiconductor device can be provided.

### EXAMPLES

Hereinafter, the present invention will be described in more detail based on examples, but the present invention is not limited to these examples.

### Step Y1: Step of Detecting Number of Defects and Position of Defects on Substrate X With Respect to Substrate X Used in Step X1

Using a dark field defect inspection device (Surfscan (registered trademark) SP7XP, manufactured by KLA-Tencor), defect inspection of a 12-inch (diameter: 300 mm) silicon wafer used for the inspection was performed, and the number of defects (defect number) and the position of the defects, which were present on the surface of the silicon wafer and had a size of 12.5 nm or greater per 1 cm² or greater, were detected. The result is defined as “E: number of defects on original substrate”.

### Step X2A and Step Z2A: Filtration of Removal Solvent

Each removal solvent was filtered using a polyethylene filter having a pore size of 10 nm, and a gallon bottle was filled with the liquid after filtration.

Step Y2: Measurement of Number of Defects and Position of Defects Derived from Removal Solvent Used in Step X2

Each of the above-described removal solvents after filtration was connected to a line of a coater (Tokyo Electron Limited, CLEAN TRACK (registered trademark) ACT (registered trademark) 12) (in a case of connection, a filter was not connected to a connection pipe). Subsequently, a 12-inch (diameter: 300 mm) silicon wafer, on which the number of defects had been inspected in advance in step Y1 described above, was coated with the removal solvent connected by the above-described method (jetted for 10 seconds at a flow rate of 75 mL/min) using the above-described coater, and baked at 100° C. for 45 seconds. Using a dark field defect inspection device (Surfscan (registered trademark) SP7^{XP}, manufactured by KLA-Tencor), the number of defects (defect number) and the position of the defects having a size of 12.5 nm or greater, present on the surface of the silicon wafer, per 1 cm² or greater were detected with respect to the wafer after the application of the removal solvent obtained by the above-described procedures. The result is defined as “F: number of defects after shaking of removal solvent”. Next, “C: number of defects of removal solvent” was determined by the following calculation formula based on the results of “E: number of defects on original substrate” and “F: number of defects after shaking of removal solvent” obtained by the various inspections.

Equation (A1): [C: number of defects of removal solvent]=[F: number of defects after shaking removal solvent]−[E: number of defects on original substrate]

### Preparation of Precursor Composition, Resist Composition, and Thermosetting Composition

The following components were used for preparing the precursor composition, the resist composition, and the thermosetting composition. (Polymer compound)

The structures of each polymer compound used is shown below. Table 1 lists copolymer compositional ratios (proportions (molar ratios) of each constitutional unit in the structural formulae) determined by ¹³C-NMR for each polymer compound. Further, the compositional ratios in Table 1 correspond to each of the polymer compounds in order from the left. In addition, Table 1 lists the weight-average molecular weight (Mw) and the polydispersity (Mw/Mn) of each of the polymer compounds, which are determined by GPC measurement, in terms of standard polystyrene.

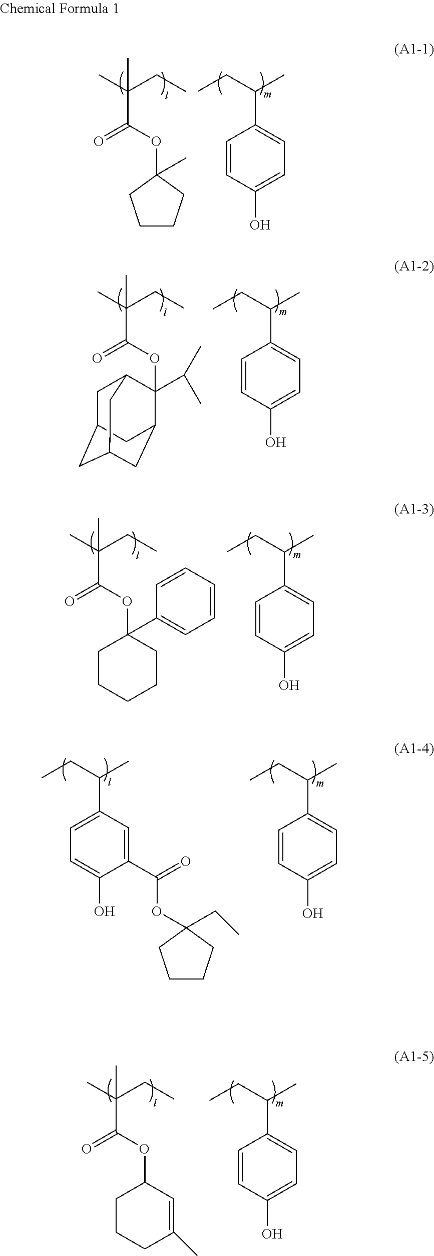

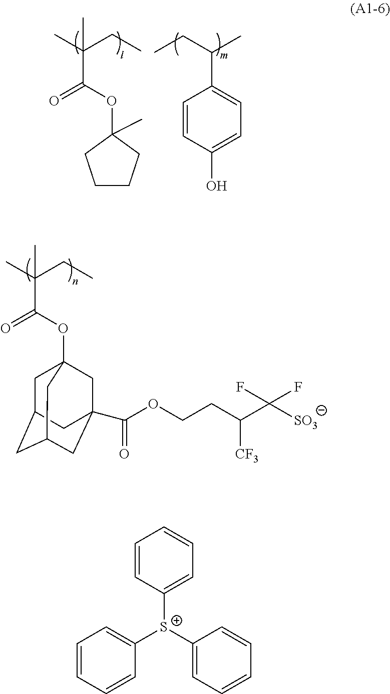

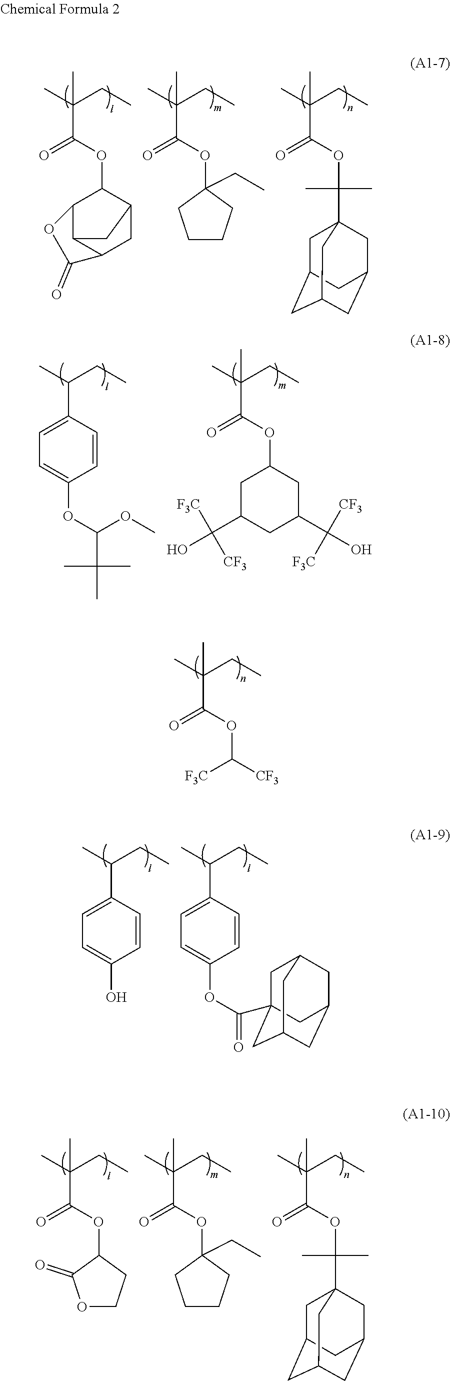

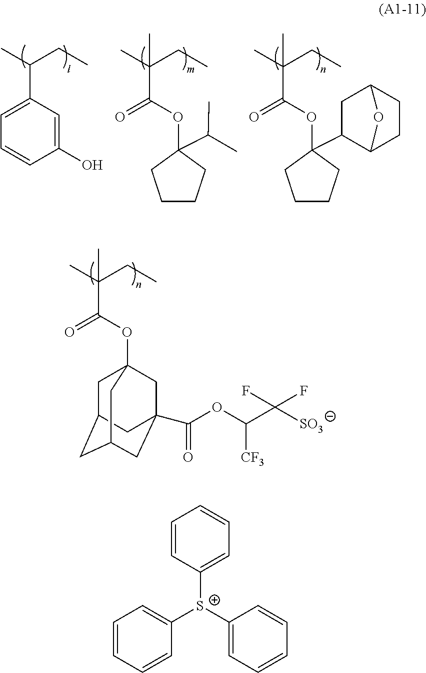

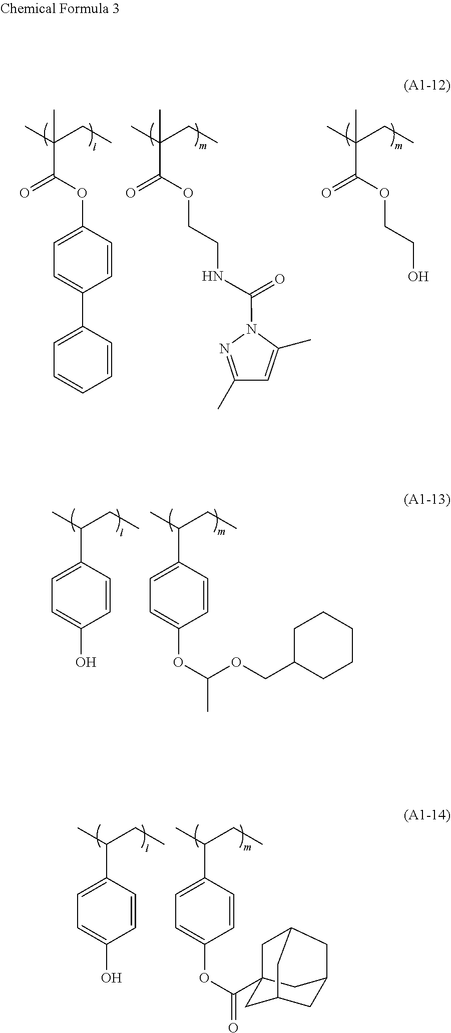

TABLE 1

| | | Weight-average | |
|---|---|---|---|
| | | molecular | |
| Polymer | | weight | Polydispersity |
| compound | Compositional ratio | (Mw) | (Mw/Mn) |
| (A1-1) | l/m = 60/40 | 5100 | 1.71 |
| (A1-2) | l/m = 60/40 | 4900 | 1.74 |
| (A1-3) | l/m = 60/40 | 5200 | 1.72 |
| (A1-4) | l/m = 60/40 | 4800 | 1.68 |
| (A1-5) | l/m = 60/40 | 5100 | 1.70 |
| (A1-6) | l/m/n = 50/35/15 | 12900 | 1.76 |
| (A1-7) | l/m/n = 40/50/10 | 9500 | 1.60 |
| (A1-8) | l/m/n = 30/50/20 | 8000 | 1.60 |
| (A1-9) | l/m = 90/10 | 3500 | 1.10 |
| (A1-10) | l/m/n = 50/40/10 | 10000 | 1.60 |
| (A1-11) | l/m/n/o = 40/30/25/5 | 6500 | 1.50 |
| (A1-12) | l/m/n = 50/25/25 | 50000 | 4.50 |
| (A1-13) | l/m = 64/36 | 3900 | 1.05 |
| (A1-14) | l/m = 85/15 | 4100 | 1.10 |

### Compound 1: Photoacid Generator and Near Infrared Absorbing Dye

The structures of each photoacid generator and each near infrared absorbing dye used as the compound 1 are shown below.

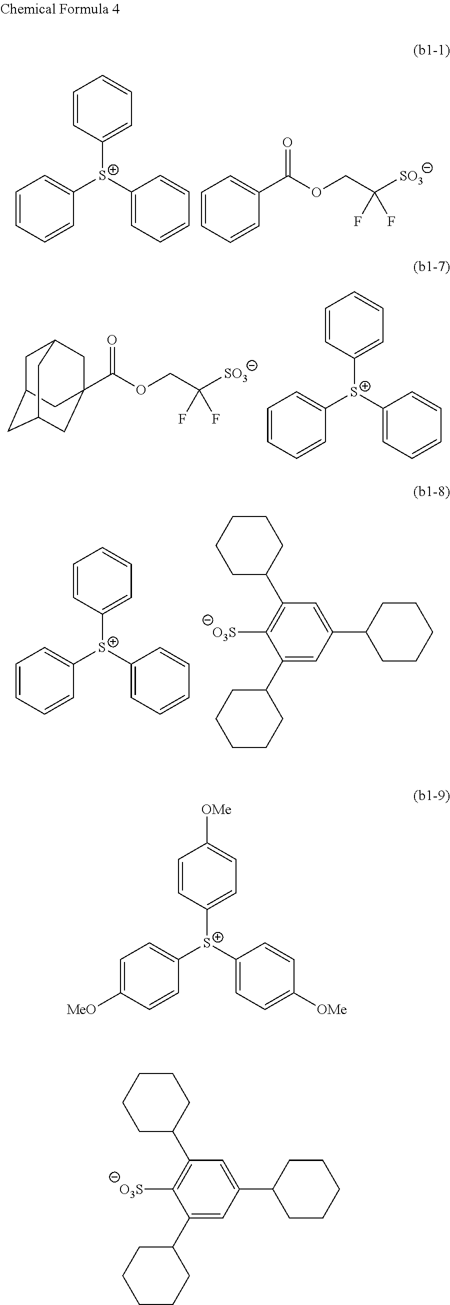

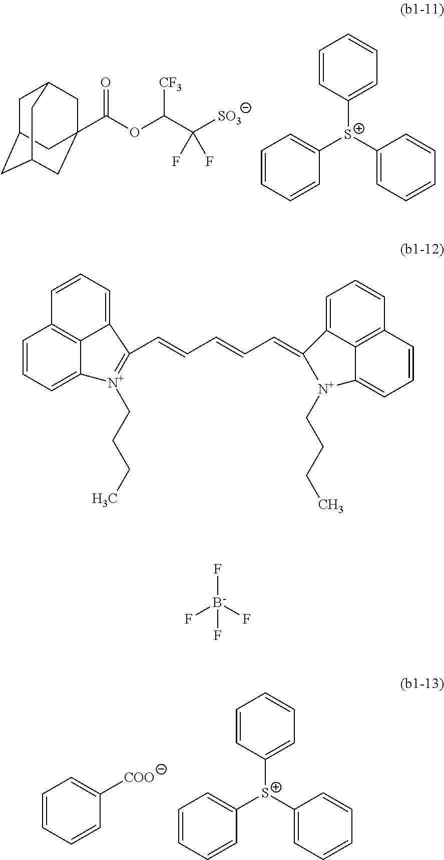

### Compound 2: Acid Diffusion Control Agent

The structures of the acid diffusion control agents used as the compound 2 are shown below.

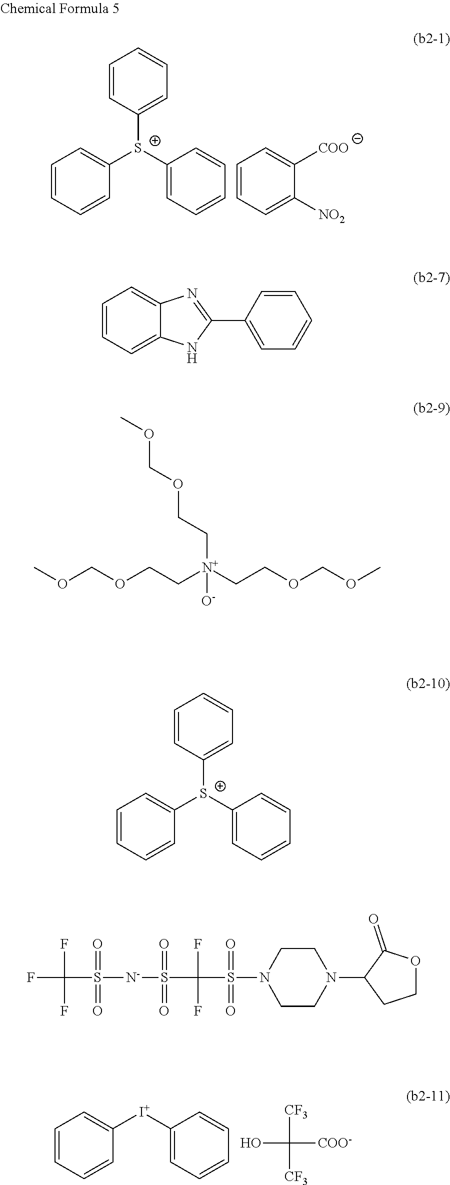

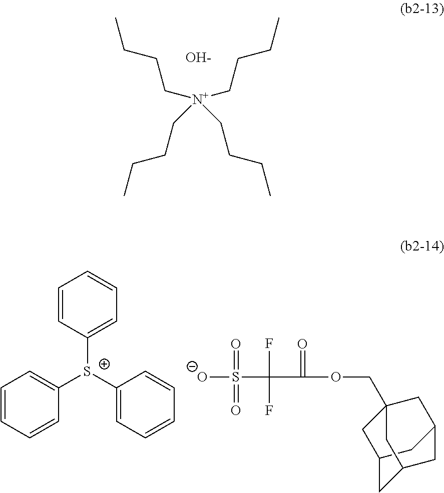

### Compound 3: Fluorine Additive and Acid Generator

The structures of each fluorine additive and each acid generator used as the compound 3 are shown below.

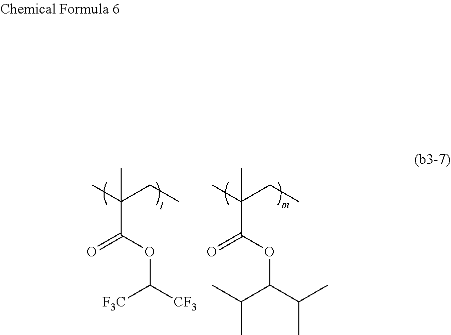

The weight-average molecular weight (Mw) determined by the GPC measurement in terms of the standard polystyrene was 15,000, and the polydispersity (Mw/Mn) thereof was 1.5. The copolymer compositional ratio (1/m) (the proportion (molar ratio) of each constitutional unit in the structural formula) determined by ¹³C-NMR was 50/50.

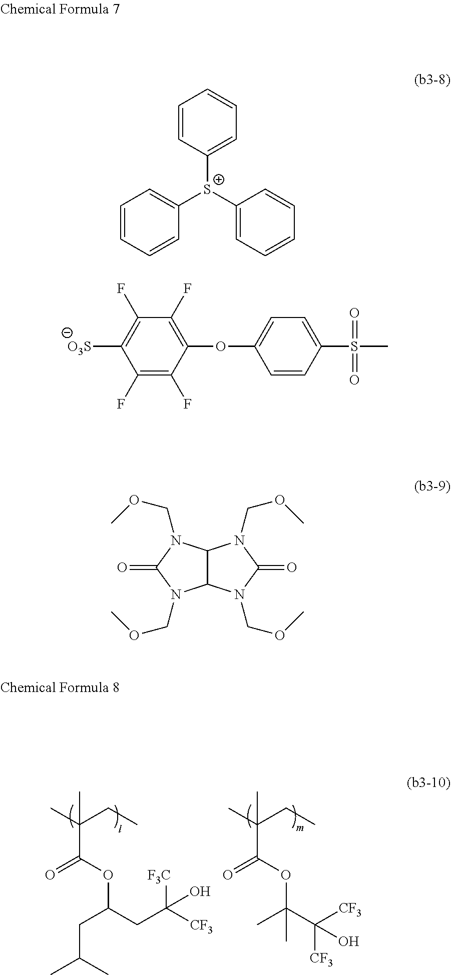

The weight-average molecular weight (Mw) determined by the GPC measurement in terms of the standard polystyrene was 10,000, and the polydispersity (Mw/Mn) thereof was 1.4. The copolymer compositional ratio (1/m) (the proportion (molar ratio) of each constitutional unit in the structural formula) determined by ¹³C-NMR was 60/40.

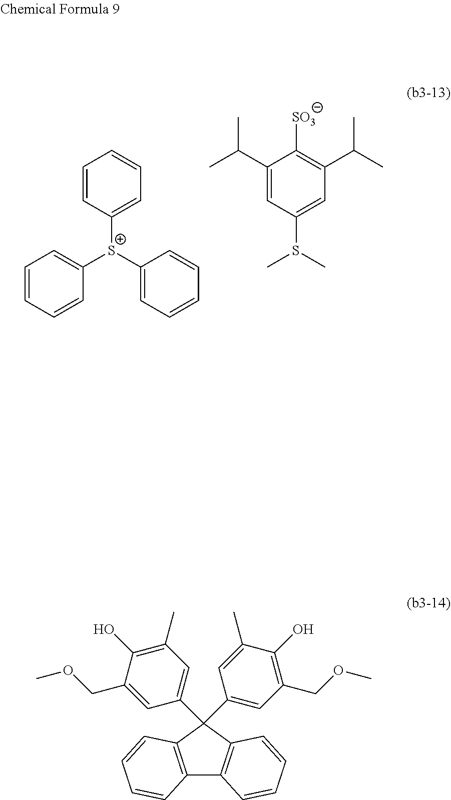

### Solvent

The solvents for a composition used are as follows.
s1: propylene glycol monomethyl ether acetate (hereinafter, “PGMEA”)
s2: propylene glycol monomethyl ether (hereinafter, “PGME”)
s3: γ-butyrolactone

The removal solvents used are as follows.
c1: mixed solution of PGMEA/PGME at ratio of 3/7
c2: 2.38% tetramethylammonium hydroxide aqueous solution (NMD-3: manufactured by TOKYO OHKA KOGYO CO., LTD.)
c3: PGMEA

### Step V: Preparation of Precursor Composition

For Examples 01 to 04 and 11 to 28 and Comparative Examples 01 to 04 and 11 to 18, a solution formed of the polymer compound and the solvent for a composition listed in Table 2 was prepared such that the solid content concentration thereof was 10% by mass. Next, the precursor composition was obtained by performing filtration once with a two-stage filter including a pore size nylon filter in the first stage and a polyethylene filter having a pore size of 1 nm in the second stage.

TABLE 2
Precursor composition

| | Polymer | Solvent | Ratio | Solvent | Ratio |
|---|---|---|---|---|---|
| Example | compound | 1 | [wt %] | 2 | [wt %] |
| Example 01 | (A1-8) | s1 | 60 | s2 | 40 |
| Precursor composition | | | | | |
| Comparative | (A1-8) | s1 | 60 | s2 | 40 |
| Example 01 | | | | | |
| Example 02 | (A1-8) | s1 | 60 | s2 | 40 |
| Comparative | (A1-8) | s1 | 60 | s2 | 40 |
| Example 02 | | | | | |
| Example 03 | (A1-14) | s1 | 60 | s2 | 40 |
| Comparative | (A1-14) | s1 | 60 | s2 | 40 |
| Example 03 | | | | | |
| Example 04 | (A1-14) | s1 | 60 | s2 | 40 |
| Comparative | (A1-14) | s1 | 60 | s2 | 40 |
| Example 04 | | | | | |
| Example 11 | (A1-1) | s1 | 60 | s2 | 40 |
| Example 12 | (A1-2) | s1 | 60 | s2 | 40 |
| Example 13 | (A1-3) | s1 | 60 | s2 | 40 |
| Example 14 | (A1-4) | s1 | 60 | s2 | 40 |
| Example 15 | (A1-5) | s1 | 60 | s2 | 40 |
| Example 16 | (A1-6) | s1 | 60 | s2 | 40 |
| Example 17 | (A1-7) | s1 | 60 | s2 | 40 |
| Example 18 | (A1-8) | s1 | 60 | s2 | 40 |
| Example 19 | (A1-9) | s1 | 60 | s2 | 40 |
| Example 20 | (A1-10) | s1 | 60 | s2 | 40 |
| Example 21 | (A1-11) | s1 | 60 | s2 | 40 |
| Example 22 | (A1-12) | s1 | 90 | s3 | 10 |
| Example 23 | (A1-1) | s1 | 60 | s2 | 40 |
| Example 24 | (A1-1) | s1 | 60 | s2 | 40 |
| Example 25 | (A1-13) | s1 | 60 | s2 | 40 |
| Example 26 | (A1-14) | s1 | 60 | s2 | 40 |
| Example 27 | (A1-14) | s1 | 60 | s2 | 40 |
| Example 28 | (A1-10) | s1 | 60 | s2 | 40 |

Step X1: Step of Coating Substrate X with Precursor Composition to Form Coating Film X

Each of the prepared precursor compositions was connected to a line of a coater (Tokyo Electron Limited, CLEAN TRACK (registered trademark) LITHIUS Pro (registered trademark) Z) (here, a line different from the solvent). In addition, during the connection, the filter was not connected to the connection pipe. Subsequently, a 12-inch (diameter: 300 mm) silicon wafer, on which the number of defects had been inspected in advance in step Y1 described above, was coated with the precursor composition connected by the above-described method at 1500 rpm using the above-described coater, and baked at 110° C. for 60 seconds to form a coating film.

### Step X2: Step of Removing Coating Film X From Substrate X Using Removal Solvent X

In Examples 01 to 04 and 11 to 28, the coating film was removed from the silicon wafer provided with the coating film obtained in the step X1 using a removal solvent. Further, the removal solvent used here is any of various solvents prepared in the step X2 and the step Z2.

### Step X3: Step of Measuring Number of Defects and Position of Defects on Substrate X After Coating Film X Was Removed, Using Defect Inspection Device X

A defect inspection was performed on the wafer after the step of removing the coating film using a dark field defect inspection device (Surfscan (registered trademark) SP7^{XP}, manufactured by KLA-Tencor), and the number of defects (defect number) with a size of 12.5 nm or greater and the position of the defects present on the surface of the silicon wafer per 1 cm² or greater were detected ([D: Total defect number after solvent removal treatment]). Next, “B: defect number after removal” was determined by the following calculation formula based on the results of “E: defect number on original substrate” and “D: total defect number after solvent removal treatment” obtained by the various inspections. Equation (A2): [B: defect number after removal]=[D: total defect number after solvent removal treatment]−[E: defect number on original substrate]

### Defect Evaluation After Peeling (Calculation Of [A: Defect Number After Peeling])

As the number of defects after peeling, a value obtained by subtracting the number of defects ([C: defect number of removal solvent]) derived from the removal solvent from the number of defects after removal was defined as “A: defect number after peeling”. Specifically, “A: defect number after peeling” was obtained by the following calculation formula. Further, [C: defect number of removal solvent] is based on the description above. Equation (A3): [A: defect number after peeling]=[B: defect number after removal]−[C: defect number of removal solvent] The number of defects after peeling per 1 cm² was evaluated according to the following evaluation standards. The results are listed in Tables 4 and 5.

### Evaluation Standards

A: The number of defects after peeling per 1 cm² was less than 0.1.
B: The number of defects after peeling per 1 cm² was 0.5 or greater and less than 2.
C: The number of defects after peeling per 1 cm² was 2 or greater and less than 10.
D: The number of defects after peeling per 1 cm² was 10 or greater.

### Evaluation of Defects of Coating Film

The defect inspection was performed on the above-described wafer provided with a coating film using a dark field defect inspection device (Surfscan (registered trademark) SP7^{XP}, manufactured by KLA-Tencor). As a result, since the inspection target was a coating film, defects with a size of less than 30 nm could not be evaluated. Therefore, as the number of defects of the coating film, a value obtained by subtracting the number of defects ([E: number of defects on original substrate]) derived from the number of defects on the original substrate from the number of defects ([B′: number of defects after coating]) of defects with a size of 30 nm or greater on the surface of the coating film and in the film per 1 cm² or greater was defined as “A′: number of defects of coating film”. Specifically, “A′: number of defects of coating film” was determined by the following calculation formula. Equation (A3′): [A′: number of defects of coating film]=[B′: number of defects after coating]−[E: number of defects on original substrate] The number of coating film defects per 1 cm² is listed in Table 4.

Step X4: Step of Superimposing Position Coordinates of Detection Result of Defect by Step Y1 and Detection Result of Defect by Step X3, and Measuring Number of Defects Derived from Resin Composition X by Subtracting Number of Defects Detected at Same Position as Position of Defect on Substrate Z Detected in Step Y1 from Number of Defects by Step X3

First, as shown in FIG. 1, the defect position in the substrate X is measured (step X41). Next, as shown in FIG. 2, the defect position in the substrate X is measured in the substrate X after the application of the resin composition X (step X42). Further, as shown in FIG. 3, the number of defects derived from the resin composition X is measured by subtracting the number of defects at the same position as the defects measured in the step X41 from the number of defects measured in the step X42 (step X43).

Since the defects detected at the same position in the step X41 and the step X42 are derived from the substrate X, the number of defects derived from the resin composition X can be appropriately measured in the step X43 by subtracting the number of defects detected at the same position.

In addition, the number of defects derived from the substrate Y or the substrate Z is measured by being subtracted from the number of defects derived from the removal solvent or the number of defects of the resist composition or the thermosetting composition (the step Y3 and the step Z4) by the same method as in the step X4.

Preparation of Resist Composition or Thermosetting Composition using Precursor Composition

In Examples 01, 03, and 11 to 28 and Comparative Examples 01 to 04, the precursor composition, the compound 1, the compound 2, the compound 3, and the solvents 1 and 2 for a composition listed in Table 3 were mixed to prepare a solution having a solid content concentration of 2% by mass. Next, the resist composition or the thermosetting composition was obtained by performing filtration once as listed in Tables 4 and 5 using a two-stage filter including a nylon filter having a pore size of 5 nm in the first stage and a polyethylene filter having a pore size of 1 nm in the second stage.

In addition, it was found that in Examples 02 and 04, the number of defects increased in a case where the resist composition was used in the defects after peeling of the precursor composition, and thus the resist composition was not prepared.

In Comparative Examples 11 to 18, the precursor compositions listed in Table 2 and the compounds 1 to 3 listed in Table 3 were mixed to prepare a solution having a solid content concentration of 2% by mass. Next, the mixture was filtered twice as listed in Table 5 with a two-stage filter including a nylon filter having a pore size of 5 nm in the first stage and a polyethylene filter having a pore size of 1 nm in the second stage, thereby obtaining a resist composition or a thermosetting composition.

Further, the values of the compounds 1 to 3 in Table 3 are values with respect to 100% by mass of the content of the polymer compound contained in the resist composition or the thermosetting composition.

TABLE 3
Resist composition or thermosetting composition

| | Com- | Content | Com- | Content | Com- | Content |
|---|---|---|---|---|---|---|
| Example | pound 1 | [wt %] | pound 2 | [wt %] | pound 3 | [wt %] |
| Example 01 | b1-12 | 1.50 | — | — | — | — |
| Comparative | b1-12 | 1.50 | — | — | — | — |
| Example 01 | | | | | | |
| Example 02 | — | — | — | — | — | — |
| Comparative | b1-12 | 1.50 | — | — | — | — |
| Example 02 | | | | | | |
| Example 03 | b1-12 | 1.50 | — | — | — | — |
| Comparative | b1-12 | 1.50 | — | — | — | — |
| Example 03 | | | | | | |
| Example 04 | — | — | — | — | — | — |
| Comparative | b1-12 | 1.50 | — | — | — | — |
| Example 04 | | | | | | |
| Example 11 | b1-1 | 16.20 | b2-1 | 6.60 | — | — |
| Example 12 | b1-1 | 16.20 | b2-1 | 6.60 | — | — |
| Example 13 | b1-1 | 16.20 | b2-1 | 6.60 | — | — |
| Example 14 | b1-1 | 16.20 | b2-1 | 6.60 | — | — |
| Example 15 | b1-1 | 16.20 | b2-1 | 6.60 | — | — |
| Example 16 | b1-1 | 16.20 | b2-1 | 6.60 | — | — |
| Example 17 | b1-7 | 7.97 | b2-7 | 1.74 | b3-7 | 0.79 |
| Example 18 | b1-8 | 10.22 | b2-7 | 1.30 | b3-8 | 10.22 |
| Example 19 | b1-9 | 14.60 | b2-9 | 2.19 | b3-9 | 29.20 |
| Example 20 | b1-7 | 12.66 | b2-10 | 0.23 | b3-10 | 0.11 |
| Example 21 | b1-11 | 11.76 | b2-11 | 5.88 | — | — |
| Example 22 | b1-12 | 1.50 | — | — | — | — |
| Example 23 | b1-7 | 12.66 | b2-10 | 0.23 | b3-10 | 0.11 |
| Example 24 | b1-7 | 12.66 | b2-10 | 0.23 | b3-10 | 0.11 |
| Example 25 | b1-13 | 6.59 | b2-13 | 1.29 | b3-13 | 21.32 |
| Example 26 | b1-13 | 7.84 | b2-14 | 12.25 | b3-14 | 43.14 |
| Example 27 | b1-12 | 1.50 | — | — | — | — |
| Example 28 | b1-7 | 12.66 | b2-10 | 0.23 | b3-10 | 0.11 |
| Comparative | b1-7 | 7.97 | b2-7 | 1.74 | b3-7 | 0.79 |
| Example 11 | | | | | | |
| Comparative | b1-8 | 10.22 | b2-7 | 1.30 | b3-8 | 10.22 |
| Example 12 | | | | | | |
| Comparative | b1-9 | 14.60 | b2-9 | 2.19 | b3-9 | 29.20 |
| Example 13 | | | | | | |
| Comparative | b1-7 | 12.66 | b2-10 | 0.23 | b3-10 | 0.11 |
| Example 14 | | | | | | |
| Comparative | b1-11 | 11.76 | b2-11 | 5.88 | — | — |
| Example 15 | | | | | | |
| Comparative | b1-12 | 1.50 | — | — | — | — |
| Example 16 | | | | | | |
| Comparative | b1-13 | 6.59 | b2-13 | 1.29 | b3-13 | 21.32 |
| Example 17 | | | | | | |
| Comparative | b1-13 | 7.84 | b2-14 | 12.25 | b3-14 | 43.14 |
| Example 18 | | | | | | |

Step Z1: Step of Coating Substrate Z with Resist Composition or Thermosetting Composition Containing Precursor Composition V to Form Coating Film Z

The substrate was coated with a resist composition or a thermosetting composition in the same manner as in the step X1 to form a coating film.

### Step Z1A: Step of Exposing Coating Film

In Example 28, the coating film Z formed in the step Z1 was selectively irradiated with an ArF excimer laser (193 nm) using an ArF liquid immersion exposure device 1900i (liquid immersion exposure device with NA 1.35 Closspole (in/o=0.78/0.97) with Pol.; liquid immersion medium: water). Next, a post-exposure bake (PEB) treatment was performed at a temperature of 90° C. for 60 seconds.

Next, solvent development was performed with butyl acetate at 23° C. for 13 seconds. Thereafter, rinsing was performed for 5 seconds using methyl isobutyl carbinol (MIBC).

Step Z2: Step of Removing Coating Film Z from Substrate Z Using Removal Solvent

The coating film Z formed in the step Z1 was removed from the substrate Z in the same manner as in the step X2.

### Step Z3: Step of Detecting Number of Defects and Position of Defects on Substrate Z After the Coating Film Z Was Removed, Using Defect Inspection Device

The number of defects and the position of the defects on the substrate Z after the step Z2 were detected using a defect inspection device in the same manner as in the step X3.

TABLE 4

| | | Precursor composition | | | | Resist composition | | | |
|---|---|---|---|---|---|---|---|---|---|
| | | Number of | | | Number | Number of | | | Number |
| | Removal | times of | Coordinate | Measurement | of | times of | Coordinate | Measurement | of |
| Example | solvent | filtration | positioning 1 | of defects 1 | defects | filtration | positioning 2 | of defects 2 | defects |
| Example 01 | c1 | 1 | Performed | Defects after | A | 1 | Performed | Defects after | A |
| | | | | peeling | | | | peeling | |
| Comparative | c1 | 1 | Performed | Defects of | 1.21 | 1 | Performed | Defects after | A |
| Example 01 | | | | coating film | | | | peeling | |
| Example 02 | c1 | 1 | Performed | Defects after | D | — | — | — | — |
| | | | | peeling | | | | | |
| Comparative | c1 | 1 | Performed | Defects of | 1.69 | 1 | Performed | Defects after | D |
| Example 02 | | | | coating film | | | | peeling | |
| Example 03 | c2 | 1 | Performed | Defects after | A | 1 | Performed | Defects after | A |
| | | | | peeling | | | | peeling | |
| Comparative | c2 | 1 | Performed | Defects of | 1.13 | 1 | Performed | Defects after | A |
| Example 03 | | | | coating film | | | | peeling | |
| Example 04 | c2 | 1 | Performed | Defects after | D | — | — | — | — |
| | | | | peeling | | | | | |
| Comparative | c2 | 1 | Performed | Defects of | 1.49 | 1 | Performed | Defects after | D |
| Example 04 | | | | coating film | | | | peeling | |

As listed in Table 4, in the resin composition including the precursor compositions with the same composition but different lots after the step V2 of filtering the precursor composition consisting of the polymer compound and PGMEA, in “defects after peeling” measured by the inspection method including the step X2 of removing the coating film from the substrate X using the removal solvent and the step X3 of measuring the number of defects on the substrate after the removal of the coating film using the defect inspection device, it was possible to find the difference between the lots in the number of defects having a size of 12.5 nm or greater per 1 cm². However, in “defects of coating film” in which the number of defects in the wafer provided with a coating film was measured without performing the step V2 of filtering the solution formed of a polymer compound and a solvent for a composition, only the number of defects having a size of 30 nm or greater per unit area could be evaluated, and the difference between the lots could not be found.

As shown in the results described above, it has been confirmed that, in the inspection method of the invention of the present application, the quality of the polymer compound used in the resist composition was easily determined as compared with the defects of the coating film in which the step X2 of removing the coating film from the substrate X using the removal solvent was not performed.

TABLE 5

| | | Precursor composition | | | | Resist composition or thermosetting composition | | | | |
|---|---|---|---|---|---|---|---|---|---|---|
| | | Number of | | | Number | | Number of | | | Number |
| | Removal | times of | Coordinate | Measurement | of | Light | times of | Coordinate | Measurement | of |
| Example | solvent | filtration | positioning 1 | of defects 1 | defects | exposure | filtration | positioning 2 | of defects 2 | defects |
| Example 11 | c1 | 1 | Performed | Defects after | A | Not | 1 | Performed | Defects after | A |
| | | | | peeling | | performed | | | peeling | |
| Example 12 | c1 | 1 | Performed | Defects after | A | Not | 1 | Performed | Defects after | A |
| | | | | peeling | | performed | | | peeling | |
| Example 13 | c1 | 1 | Performed | Defects after | A | Not | 1 | Performed | Defects after | A |
| | | | | peeling | | performed | | | peeling | |
| Example 14 | c1 | 1 | Performed | Defects after | A | Not | 1 | Performed | Defects after | A |
| | | | | peeling | | performed | | | peeling | |
| Example 15 | c1 | 1 | Performed | Defects after | A | Not | 1 | Performed | Defects after | A |
| | | | | peeling | | performed | | | peeling | |
| Example 16 | c1 | 1 | Performed | Defects after | A | Not | 1 | Performed | Defects after | A |
| | | | | peeling | | performed | | | peeling | |
| Example 17 | c1 | 1 | Performed | Defects after | A | Not | 1 | Performed | Defects after | A |
| | | | | peeling | | performed | | | peeling | |
| Example 18 | c1 | 1 | Performed | Defects after | A | Not | 1 | Performed | Defects after | A |
| | | | | peeling | | performed | | | peeling | |
| Example 19 | c1 | 1 | Performed | Defects after | A | Not | 1 | Performed | Defects after | A |
| | | | | peeling | | performed | | | peeling | |
| Example 20 | c1 | 1 | Performed | Defects after | A | Not | 1 | Performed | Defects after | A |
| | | | | peeling | | performed | | | peeling | |
| Example 21 | c1 | 1 | Performed | Defects after | A | Not | 1 | Performed | Defects after | A |
| | | | | peeling | | performed | | | peeling | |
| Example 22 | c1 | 1 | Performed | Defects after | A | Not | 1 | Performed | Defects after | A |
| | | | | peeling | | performed | | | peeling | |
| Example 23 | c1 | 1 | Not | Defects after | B | Not | 1 | Not | Defects after | B |
| | | | performed | peeling | | performed | | performed | peeling | |
| Example 24 | c3 | 1 | Performed | Defects after | A | Not | 1 | Performed | Defects after | A |
| | | | | peeling | | performed | | | peeling | |
| Example 25 | c2 | 1 | Performed | Defects after | A | Not | 1 | Performed | Defects after | A |
| | | | | peeling | | performed | | | peeling | |
| Example 26 | c2 | 1 | Performed | Defects after | A | Not | 1 | Performed | Defects after | A |
| | | | | peeling | | performed | | | peeling | |
| Example 27 | c2 | 1 | Not | Defects after | B | Not | 1 | Not | Defects after | B |
| | | | performed | peeling | | performed | | performed | peeling | |
| Example 28 | c1 | 1 | Performed | Defects after | A | Performed | 1 | Performed | Defects after | A |
| | | | | peeling | | | | | peeling | |
| Comparative | c1 | 0 | — | None | — | Not | 2 | Performed | Defects after | D |
| Example 11 | | | | | | performed | | | peeling | |
| Comparative | c1 | 0 | — | None | — | Not | 2 | Performed | Defects after | D |
| Example 12 | | | | | | performed | | | peeling | |
| Comparative | c1 | 0 | — | None | — | Not | 2 | Performed | Defects after | D |
| Example 13 | | | | | | performed | | | peeling | |
| Comparative | c1 | 0 | — | None | — | Not | 2 | Performed | Defects after | D |
| Example 14 | | | | | | performed | | | peeling | |
| Comparative | c1 | 0 | — | None | — | Not | 2 | Performed | Defects after | D |
| Example 15 | | | | | | performed | | | peeling | |
| Comparative | c1 | 0 | — | None | — | Not | 2 | Performed | Defects after | D |
| Example 16 | | | | | | performed | | | peeling | |
| Comparative | c2 | 0 | — | None | — | Not | 2 | Performed | Defects after | D |
| Example 17 | | | | | | performed | | | peeling | |
| Comparative | c2 | 0 | — | None | — | Not | 2 | Performed | Defects after | D |
| Example 18 | | | | | | performed | | | peeling | |

As listed in Table 5, a resist composition having a small number of defects could be prepared by applying the inspection method of the present application and filtering the resist composition or the thermosetting composition once. On the contrary, in a case where the step V2 of filtering the precursor composition formed of a polymer compound and a solvent was not performed, even in a case where the filtration of the resist composition or the thermosetting composition was performed twice thereafter, the number of defects in the resist composition or the thermosetting composition was large. In addition, it was better not to expose the resist composition or the thermosetting composition. Further, by performing the coordinate positioning, the number of defects derived from the removal solvent or the composition could be appropriately measured by suppressing the mixing of the detection amount derived from the original substrate unrelated to the composition, which is the purpose of the evaluation. Further, since the number of defects intended to be determined by the subtraction using the coordinate positioning is accurately obtained, the cleanliness of the initial state of the wafer to be used does not need to be particularly determined.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

### EXPLANATION OF REFERENCES

X: substrate

41, 41′, 42, 43: defect

What is claimed is:

1. An inspection method comprising:
a step V of filtering a precursor composition V containing a polymer compound and a solvent V;
a step X1 of coating a substrate X with a resin composition X containing the precursor composition to form a coating film X;
a step X2 of removing the coating film X from the substrate X using a removal solvent X including at least one selected from the group consisting of an organic solvent X, an alkali developing solution X, and water; and
a step X3 of measuring the number of defects on the substrate X after the coating film X is removed, using a defect inspection device.

2. The inspection method according to claim 1, further comprising:
a step Z1 of coating a substrate Z with a resist composition or a thermosetting composition containing the precursor composition V to form a coating film Z;
a step Z2 of removing the coating film Z from the substrate Z using a removal solvent Z including at least one selected from the group consisting of an organic solvent Z, an alkali developing solution Z, and water; and
a step Z3 of measuring the number of defects on the substrate Z after the coating film Z is removed, using the defect inspection device.

3. The inspection method according to claim 1, further comprising before the step X1 or the step Z1, a step Y1 of detecting a position of a defect on the substrate X or the substrate Z using the defect inspection device with respect to the substrate X or the substrate Z used in the step X1 or the step Z1.

4. The inspection method according to claim 3, further comprising a step X4 of superimposing position coordinates of a detection result of a defect by the step Y1 and a detection result of a defect by the step X3, and measuring the number of defects derived from the resin composition X by subtracting the number of defects detected at the same position as the position of the defect on the substrate Z detected in the step Y1 from the number of defects by the step X3.

5. The inspection method according to claim 1, wherein a size of a defect measured in at least one selected from the group consisting of the step X3, the step Z3, or the step Y1 is 12.5 nm or greater.

6. The inspection method according to claim 1, wherein the resin composition is non-photosensitive.

7. The inspection method according to claim 1, wherein the resin composition consists of the polymer compound and the solvent V.

8. The inspection method according to claim 1, wherein the step X2 is applied in a state where the coating film X has not been subjected to an exposure treatment by irradiation with an actinic ray or a radiation.

9. The inspection method according to claim 1, wherein the step X2 is applied in a state where the coating film X has been subjected to an exposure treatment by irradiation with an actinic ray or a radiation.

10. A resin solution comprising:
a polymer compound; and
a solvent V,
wherein the number of defects having a size of 12.5 nm or greater per 1 cm², which is measured under the following measurement conditions, is 2 or less:
(1) a precursor composition containing the polymer compound and the solvent V is filtered,
(2) a substrate X is coated with a resin composition X containing the precursor composition to form a coating film X,
(3) the coating film X is removed from the substrate X using a removal solvent X including at least one selected from the group consisting of an organic solvent, an alkali developing solution, and water, and
(4) the number of defects on the substrate X after the coating film X is removed is measured using a defect inspection device.

11. A resist composition or a thermosetting composition, comprising the resin solution according to claim 10.

12. A method of producing a resin composition, comprising:
a step V of filtering a precursor composition containing a polymer compound and a solvent V;
a step X1 of coating a substrate X with a resin composition X containing the precursor composition to form a coating film X;
a step X2 of removing the coating film X from the substrate X using a removal solvent X including at least one selected from the group consisting of an organic solvent, an alkali developing solution, and water;
a step X3 of measuring the number of defects on the substrate X after the coating film X is removed, using a defect inspection device; and
a step R1 of providing a resin composition satisfying a predetermined number of defects in the step X3.

13. A method of producing a resist composition or a thermosetting composition, the method comprising:
a step R11 of providing a resin composition by the method of producing a resin composition according to claim 12; and
a step R12 of providing a resist composition or a thermosetting composition containing the resin composition.
